(19) United States
(12) Patent Application Publication
(10) Pub. No.: US 2015/0102345 A1
(43) Pub. Date: Apr. 16, 2015

(54) ACTIVE DEVICE AND MANUFACTURING METHOD THEREOF

(71) Applicant: E Ink Holdings Inc., Hsinchu (TW)

(72) Inventors: Chih-Hsiang Yang, Hsinchu (TW); Ted-Hong Shinn, Hsinchu (TW); Wei-Tsung Chen, Hsinchu (TW); Hsing-Yi Wu, Hsinchu (TW)

(73) Assignee: E Ink Holdings Inc., Hsinchu (TW)

(21) Appl. No.: 14/210,466

(22) Filed: Mar. 14, 2014

(30) Foreign Application Priority Data
Oct. 11, 2013 (TW) 10216819

(51) Int. Cl. H01L 29/786; H01L 29/66

(52) U.S. Cl. CPC H01L 29/7869; H01L 29/66969
USPC 257/66; 438/158

(57) ABSTRACT

An active device includes a gate, a gate insulation layer, a channel layer, a first passivation layer, a second passivation layer, a source and a drain. The gate insulation layer is disposed on the substrate and covers the gate. The channel layer is disposed on the gate insulation layer and has a semiconductor section disposed corresponding to the gate and a conductive section located around the semiconductor section. The first passivation layer is disposed on the channel layer and covers the semiconductor section. The second passivation layer is disposed on and covers the first passivation layer. The source and the drain are disposed on the gate insulation layer, and extended along peripheries of the conductive section, the first and the second passivation layers to be disposed on the second passivation layer. A portion of the second passivation layer is exposed between the source and the drain.

### CROSS-REFERENCE TO RELATED APPLICATION

This application claims the priority benefit of Taiwan application serial no. 102136819, filed on Oct. 11, 2013. The entirety of the above-mentioned patent application is hereby incorporated by reference herein and made a part of this specification.

### BACKGROUND OF THE INVENTION

1. Field of the Invention

The invention relates to a semiconductor device and a manufacturing method thereof, and more particularly, to an active device and a manufacturing method thereof.

2. Description of Related Art

In a typical thin film transistor (TFT) array substrate, amorphous silicon (a-Si) TFTs or low-temperature poly-silicon TFTs are usually used as switching elements for various sub-pixels. In recent years, studies have shown that an oxide semiconductor TFT has higher carrier mobility than the a-Si TFT, and the oxide semiconductor TFT is advantageous over the low-temperature poly-silicon TFT in large-area and low-cost fabrication. Therefore, the oxide semiconductor TFT has the potential to become a key element for the next-generation flat panel display.

Elements in a bottom gate thin film transistor (bottom gate TFT) structure of conventional art are formed in following sequence: a gate, a gate insulation layer, a channel layer, a source and drain, a passivation layer and a planer layer. Therein, the passivation layer is formed to cover the source, the drain and the channel layer exposed between the source and the drain after the source and the drain are formed on the channel layer. Therefore, in case an etchant is used to etch a second metal layer to form the source and the drain and define a length of a channel, an etching selectivity ratio of the etchant is not high. Accordingly, it is overly difficult to control an etching process for forming the source and the drain, thereby influencing a performance and a reliability of the bottom gate TFT.

### SUMMARY OF THE INVENTION

The invention provides to an active device which has a more preferable device performance.

The invention also provides a manufacturing method of an active device for manufacturing above-said active device.

The active device of the invention is disposed on a substrate, and includes a gate, a gate insulation layer, a channel layer, a first passivation layer, a second passivation layer, a source and a drain. The gate insulation layer is disposed on the substrate and covers the gate. The channel layer is disposed on the gate insulation layer, and has a semiconductor section and a conductive section located around the semiconductor section. The semiconductor section is disposed corresponding to the gate. The first passivation layer is disposed on the channel layer and covers the semiconductor section. The second passivation layer is disposed on the first passivation layer, and covers the first passivation layer. The source and the drain are disposed on the gate insulation layer, and extended along peripheries of the conductive section, the first and the second passivation layers to be disposed on the second passivation layer. A portion of the second passivation layer is exposed between the source and the drain.

In an embodiment of the invention, a thickness of the second passivation layer is more than eight times a thickness of the first passivation layer.

In an embodiment of the invention, the first passivation layer is composed of an oxygen compound.

In an embodiment of the invention, the second passivation layer is composed of a nitrogen compound.

In an embodiment of the invention, the active device further includes a planar layer. The planar layer is disposed on the substrate and covers the source, the drain and the portion of the second passivation layer exposed between the source and the drain.

In an embodiment of the invention, an orthogonal projection of the semiconductor section of the channel layer on the substrate is completely overlapped with an orthogonal projection of the gate on the substrate. An area of the orthogonal projection of the semiconductor section on the substrate is less than or equal to an area of the orthogonal projection of the gate on the substrate.

In an embodiment of the invention, an orthogonal projection of the conductive section of the channel layer on the substrate is not overlapped with an orthogonal projection of the second passivation layer on the substrate.

The manufacturing method of the active device according to the invention includes the following steps. A gate is formed on a substrate. A gate insulation layer is formed on the substrate, and the gate insulation layer covers the gate. A channel layer is formed on the gate insulation layer. A first passivation layer is formed on the channel layer. A passivation material layer covering the gate insulation layer, the channel layer and the first passivation layer is formed. An annealing process is performed on the passivation material layer to define a semiconductor section and a conductive section on the channel layer, in which the semiconductor section is disposed corresponding to the gate and the first passivation layer, and the conductive section is located around the semiconductor section. A patterning process is performed on the passivation material layer to form a second passivation layer, in which the second passivation layer is located at the semiconductor section and covers the first passivation layer. A source and a drain are formed on the gate insulation layer, and the source and the drain are extended along peripheries of the conductive section, the first passivation layer and the second passivation layer to be disposed on the second passivation layer, in which a portion of the second passivation layer is exposed between the source and the drain.

In an embodiment of the invention, a thickness of the second passivation layer is more than eight times a thickness of the first passivation layer.

In an embodiment of the invention, the first passivation layer is composed of an oxygen compound.

In an embodiment of the invention, the second passivation layer is composed of a nitrogen compound.

In an embodiment of the invention, the manufacturing method of the active device further includes: forming a planar layer on the substrate after the source and the drain are formed, in which the planar layer covers the source, the drain and the portion of the second passivation layer exposed between the source and the drain.

In an embodiment of the invention, an orthogonal projection of the semiconductor section of the channel layer on the substrate is completely overlapped with an orthogonal projection of the gate on the substrate, and an area of the orthogonal projection of the semiconductor section on the substrate is less than or equal to an area of the orthogonal projection of the gate on the substrate.

In an embodiment of the invention, an orthogonal projection of the conductive section of the channel layer on the substrate is not overlapped with an orthogonal projection of the second passivation layer on the substrate.

Based on above, in the active device of the invention, the source and the drain are formed after the first passivation layer and the second passivation layer are formed on the channel layer. As compared to the conventional method in which the passivation layers are formed after the source and the drain are formed on the channel layer, besides that the first passivation layer may server as the self-align mask of the channel layer for defining the semiconductor section and protect the second passivation layer from damages during the process of forming the second passivation layer, in the active device of the invention, the second passivation layer may also be used to isolate influences of moisture and oxygen from the outside to the channel layer. Moreover, the section of the channel layer not covered by the first passivation layer may become the conductive section due to the annealing process, and the source and the drain are extended along the conductive section to be disposed on the passivation layer in subsequent process. Accordingly, the metal work function of the semiconductor section is similar to the metal work function of the source and the drain, the contact impedance may be significantly reduced and the performance and the reliability in electrical property of the active device formed subsequently may be improved.

To make the above features and advantages of the disclosure more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the invention.

FIG. 1 is a schematic cross-sectional view of an active device according to an embodiment of the invention.

FIG. 2A to FIG. 2B are schematic cross-sectional views illustrating a manufacturing method of an active device according to an embodiment of the invention.

### DESCRIPTION OF EMBODIMENTS

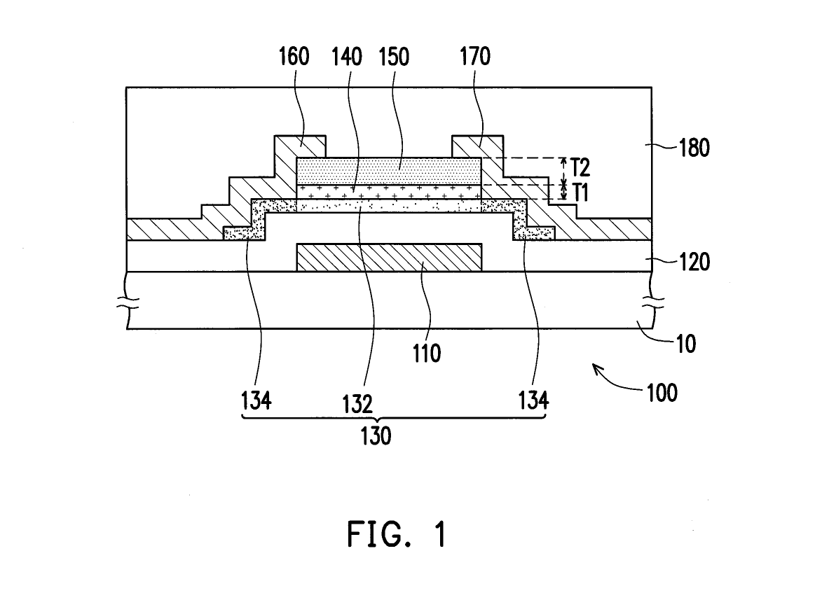

FIG. 1 is a schematic cross-sectional view of an active device according to an embodiment of the invention. Referring to FIG. 1, in the present embodiment, an active device 100 is disposed on a substrate 10, and the active device 100 includes a gate 110, a gate insulation layer 120, a channel layer 130, a first passivation layer 140, a second passivation layer 150, a source 160 and a drain 170. Herein, the substrate 10 is a glass substrate for example, but the invention is not limited thereto.

More specifically, the gate insulation layer 120 is disposed on the substrate 10, and covers the gate 110 and a portion of the substrate 10 exposed by the gate 110. The channel layer 130 is disposed on the gate insulation layer 120, and has a semiconductor section 132 and a conductive section 134 located around the semiconductor section 132. The semiconductor section 132 is disposed corresponding to the gate 110. The first passivation layer 140 is disposed on the channel layer 130 and covers the semiconductor section 132. The second passivation layer 150 is disposed on the first passivation layer 140, and covers the first passivation layer 140. The source 160 and the drain 170 are disposed on the gate insulation layer 120, and extended along peripheries of the conductive section 134 of the channel layer 130, the first passivation layer 140 and the second passivation layer 150 to be disposed on the second passivation layer 150. A portion of the second passivation layer 150 is exposed between the source 160 and the drain 170. As shown in FIG. 1, in the present embodiment, the active device 100 composed of the gate 110, the gate insulation layer 120, the channel layer 130, the first passivation layer 140, the second passivation layer 150, the source 160 and the drain 170 is substantially a bottom gate TFT.

Furthermore, as shown in FIG. 1, an orthogonal projection of the semiconductor section 132 of the channel layer 130 on the substrate 10 is completely overlapped with an orthogonal projection of the gate 110 on the substrate 10, and an area of the orthogonal projection of the semiconductor section 132 on the substrate 10 is less than an area of the orthogonal projection of the gate 110 on the substrate 10. Naturally, in other embodiments not illustrated, the area of the orthogonal projection of the semiconductor section 132 of the channel layer 130 on the substrate 10 may also be equal to the area of the orthogonal projection of the gate 110 on the substrate 10. In other words, a position of the semiconductor section 132 of the channel layer 130 is substantially disposed corresponding to a position of the gate 110. On the other hand, an orthogonal projection of the conductive section 134 of the channel layer 130 on the substrate 10 is not overlapped with an orthogonal projection of the second passivation layer 150 on the substrate 10. In other words, the second passivation layer 150 does not cover the conductive section 134 of the channel layer 130.

More preferably, a material of the first passivation layer 140 is substantially different from a material of the second passivation layer 150, herein, the first passivation layer 140 is composed of an oxygen compound, and the second passivation layer 150 is composed of a nitrogen compound and has a more preferable insulating capability. The first passivation layer 140 may serve as a self-align mask of the channel layer 130 for defining the semiconductor section 132, and protect the channel layer 130 from damages during a process of forming the second passivation layer 150. The second passivation layer 150 may be used to isolate influences of moisture and oxygen from the outside to the channel layer 130. In particular, a thickness T2 of the second passivation layer 150 is more than eight times a thickness T1 of the first passivation layer 140.

Because that the source 160 and the drain 170 are extended along the peripheries of the conductive section 134 of the channel layer 130, the first passivation layer 140 and the second passivation layer 150 to be disposed on the second passivation layer 150, and the thickness T2 of the second passivation layer 150 is far greater than the thickness T1 of the first passivation layer 140, thus, when moisture and oxygen from the outside (not illustrated) enter from boundaries between the source 160, the drain 170 and the second passivation layer 150, the second passivation layer 150 may effectively delay or isolate a contacted amount of moisture and oxygen from the outside to the channel layer 130, so that the active device 100 may provide a more preferable reliability and electric property. In addition, the active device 100 of the present embodiment further includes a planar layer 180. The planar layer 180 is disposed on the substrate 10, and covers the source 160, the drain 170 and the portion of the second passivation layer 150 exposed between the source 160 and the drain 170.

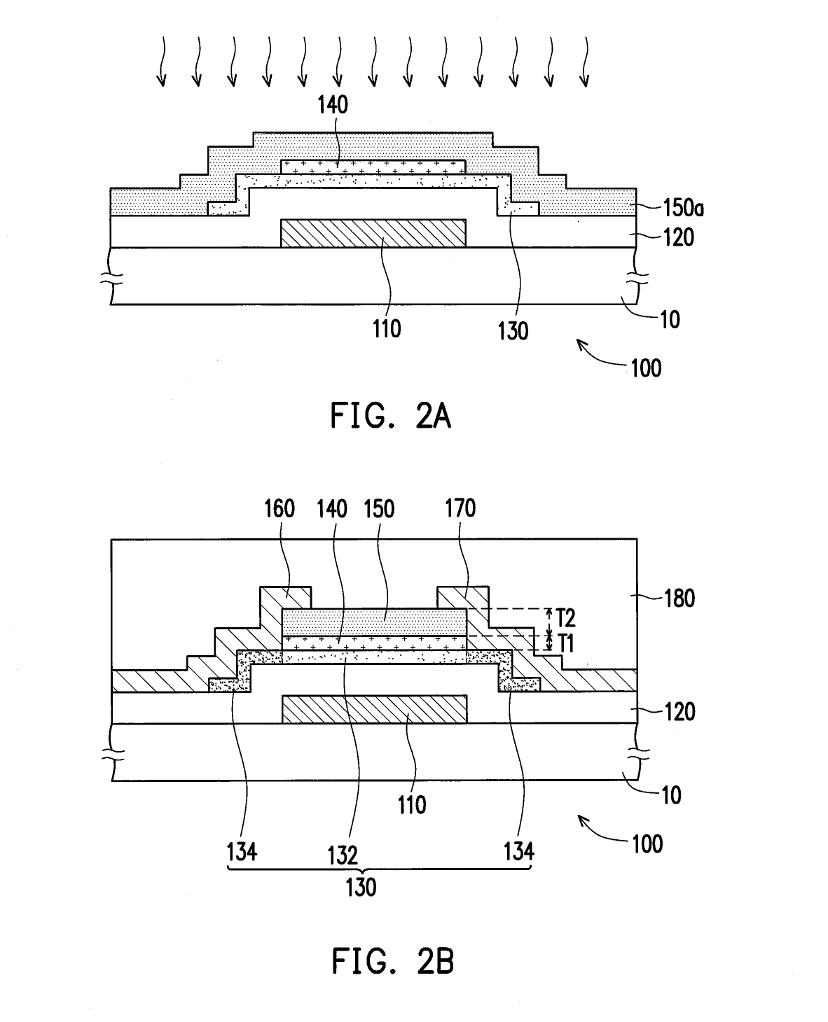

The foregoing description is provided to introduce a structure of the active device 100 of the invention but a manufacturing method of the active device 100 of the invention. Hereinafter, detailed description of the manufacturing method of the active device 100 is provided below by using the structure of the active device 100 depicted in FIG. 1 as an example with reference to FIG. 2A to FIG. 2B.

FIG. 2A to FIG. 2B are schematic cross-sectional views illustrating a manufacturing method of an active device according to an embodiment of the invention. Referring to FIG. 2A, based on the manufacturing method of the active device 100 according to the present embodiment, first, a gate 110 is formed on a substrate 10, in which the substrate 10 is a glass substrate for example. Next, a gate insulation layer 120 is formed on the substrate 10, and the gate insulation layer 120 covers the gate 110 and a portion of the substrate 10 exposed by the gate 110. Next, referring to FIG. 2A, a channel layer 130 is formed on the gate insulation layer 120. The channel layer 130 is disposed at least corresponding to the gate 110, and a material of the channel layer 130 is, for example a metal oxide such as an indium gallium zinc oxide or an indium tin zinc oxide. Herein, an orthographic projection of the channel layer 130 on the substrate 10 is greater than an orthographic projection of the gate 110 on the substrate 10. Next, a first passivation layer 140 is formed on the channel layer 130, in which an orthographic projection of the first passivation layer 140 on the substrate 10 is less than the orthographic projection of the gate 110 on the substrate 10. Naturally, in other embodiments not illustrated, the orthographic projection of the first passivation layer 140 on the substrate 10 may also be equal to the orthographic projection of the gate 110 on the substrate 10. Thereafter, a passivation material layer 150a is formed to cover the gate insulation layer 120, the channel layer 130 and the first passivation layer 140.

Referring to FIG. 2A and FIG. 2B together, subsequently, an annealing process is performed on the passivation material layer 150a to define a semiconductor section 132 and a conductive section 134 on the channel layer 130, in which the semiconductor section 132 is disposed corresponding to the gate 110 and the first passivation layer 140, and the conductive section 134 is located around the semiconductor section 132. Furthermore, an orthogonal projection of the semiconductor section 132 of the channel layer 130 on the substrate 10 is completely overlapped with an orthogonal projection of the gate 110 on the substrate 10, and an area of the orthogonal projection of the semiconductor section 132 on the substrate 10 is less than an area of the orthogonal projection of the gate 110 on the substrate 10. Naturally, in other embodiments not illustrated, the area of the orthogonal projection of the semiconductor section 132 of the channel layer 130 on the substrate 10 may also be equal to the area of the orthogonal projection of the gate 110 on the substrate 10. The area of the orthogonal projection of the semiconductor section 132 is decided based on a size of the first passivation layer 140 being disposed. On the other hand, an orthogonal projection of the conductive section 134 of the channel layer 130 on the substrate 10 is not overlapped with an orthogonal projection of the second passivation layer 150 on the substrate 10. In other words, the second passivation layer 150 does not cover the conductive section 134 of the channel layer 130.

It should be noted that, since the first passivation layer 140 covers a portion of the channel layer 130, when the annealing process is performed, a material characteristic of a section of the channel layer 130 covered by the first passivation layer 140 (i.e., the semiconductor section 132) remains unchanged, namely, a characteristic of semiconductor is provided. On the other hand, a material characteristic of a section of the channel layer 130 not covered by the first passivation layer 140 (i.e. the conductive section 134) is converted from the characteristic of semiconductor into a characteristic of conductor due to the annealing process. In other words, the first passivation layer 140 may be disposed to serve as the self-align mask of the channel layer 130 for defining the semiconductor section 132.

Next, referring back to FIG. 2A and FIG. 2B together, a patterning process is performed on the passivation material layer 150a to form a second passivation layer 150, in which the second passivation layer 150 is located at the semiconductor section 132 and covers the first passivation layer 140. Because the first passivation layer 140 is disposed on the semiconductor section 132 of the channel layer 130, the semiconductor section 132 may be protected from damages during the process of forming the second passivation layer 150. More preferably, a material of the first passivation layer 140 is different from a material of the second passivation layer 150, herein, the first passivation layer 140 is composed of an oxygen compound, and the second passivation layer 150 is composed of a nitrogen compound and has a more preferable insulating capability. A thickness T2 of the second passivation layer 150 is more than eight times a thickness T1 of the first passivation layer 140.

Next, referring back to FIG. 2B, a source 160 and a drain 170 are formed on the gate insulation layer 120. The source 160 and the drain 170 are extended along a periphery of the conductive section 134 of the channel layer 130, a periphery of the first passivation layer 140 and a periphery of the second passivation layer 150 to be disposed on the second passivation layer 150, in which a portion of the second passivation layer 150 is exposed between the source 160 and the drain 170. Since the section of the channel layer 130 not covered by the first passivation layer 140 forms the conductive section 134 due to the annealing process, in case the source 160 and the drain 170 are extended along the conductive section 134 to be disposed on the second passivation layer 150, a metal work function of the conductive section 134 is similar to a metal work function of the source 160 and the drain 170, such that a contact impedance may be significantly reduced, and a performance and a reliability in electrical property of the active device 100 formed subsequently may be improved. It should be noted that, the metal work function herein refers a measurement of a minimum energy required for retrieving electron from a metal surface.

In addition, since the source 160 and the drain 170 are formed after the first passivation layer 140 and the second passivation layer 150 are formed on the channel layer 130 in the present embodiment, the semiconductor section 132 of the channel layer 130 may be protected by the first passivation layer 140 and the second passivation layer 150 in the active device 100 of the present embodiment, so as to effectively isolate influences of moisture and oxygen from the outside to the channel layer 130. Lastly, referring back to FIG. 2B, a planar layer 180 is disposed on the substrate 10. The planar layer 180 covers the source 160, the drain 170 and the portion of the second passivation layer 150 exposed between the source 160 and the drain 170. Thereby, manufacturing of the active components 100 is completed.

Based on above, in the active device of the invention, the source and the drain are formed after the first passivation layer and the second passivation layer are formed on the channel layer. As compared to the conventional method in which the passivation layers are formed after the source and the drain are formed on the channel layer, besides that the first passivation layer may server as the self-align mask of the channel layer for defining the semiconductor section and protect the second passivation layer from damages during the process of forming the second passivation layer, in the active device of the invention, the second passivation layer may also be used to isolate influences of moisture and oxygen from the outside to the channel layer. Moreover, the section of the channel layer not covered by the first passivation layer may become the conductive section due to the annealing process, and the source and the drain are extended along the conductive section to be disposed on the passivation layer in subsequent process. Accordingly, the metal work function of the semiconductor section is similar to the metal work function of the source and the drain, the contact impedance may be significantly reduced and the performance and the reliability in electrical property of the active device formed subsequently may be improved.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims and their equivalents.

1. An active device disposed on a substrate, and the active device comprising:
a gate;
a gate insulating layer disposed on the substrate and covering the gate;
a channel layer disposed on the gate insulation layer, and having a semiconductor section and a conductive section located around the semiconductor section, wherein the semiconductor section is disposed corresponding to the gate;
a first passivation layer disposed on the channel layer, and covering the semiconductor section;
a second passivation layer disposed on the first passivation layer, and covering the first passivation layer; and
a source and a drain, disposed on the gate insulation layer, and extended along peripheries of the conductive section, the first passivation layer and the second passivation layer to be disposed on the second passivation layer, wherein a portion of the second passivation layer is exposed between the source and the drain.

2. The active device as recited in claim 1, wherein a thickness of the second passivation layer is more than eight times a thickness of the first passivation layer.

3. The active device as recited in claim 1, wherein the first passivation layer is composed of an oxygen compound.

4. The active device as recited in claim 1, wherein the second passivation layer is composed of a nitrogen compound.

5. The active device as recited in claim 1, further comprising:
a planar layer disposed on the substrate and covering the source, the drain and the portion of the second passivation layer exposed between the source and the drain.

6. The active device as recited in claim 1, wherein an orthogonal projection of the semiconductor section of the channel layer on the substrate is completely overlapped with an orthogonal projection of the gate on the substrate, and an area of the orthogonal projection of the semiconductor section on the substrate is less than or equal to an area of the orthogonal projection of the gate on the substrate.

7. The active device as recited in claim 1, wherein an orthogonal projection of the conductive section of the channel layer on the substrate is not overlapped with an orthogonal projection of the second passivation layer on the substrate.

8. A manufacturing method of an active device, comprising:
forming a gate on a substrate;
forming a gate insulation layer on the substrate, and the gate insulation layer covering the gate;
forming a channel layer on the gate insulation layer;
forming a first passivation layer on the channel layer;
forming a passivation material layer covering the gate insulation layer, the channel layer and the first passivation layer;
performing an annealing process on the passivation material layer to define a semiconductor section and a conductive section on the channel layer, wherein the semiconductor section is disposed corresponding to the gate and the first passivation layer, and the conductive section is located around the semiconductor section;
performing a patterning process on the passivation material layer to form a second passivation layer, wherein the second passivation layer is located at the semiconductor section and covers the first passivation layer; and
forming a source and a drain on the gate insulation layer, and the source and the drain being extended along peripheries of the conductive section, the first passivation layer and the second passivation layer to be disposed on the second passivation layer, wherein a portion of the second passivation layer is exposed between the source and the drain.

9. The manufacturing method of the active device as recited in claim 8, wherein a thickness of the second passivation layer is more than eight times a thickness of the first passivation layer.

10. The manufacturing method of the active device as recited in claim 8, wherein the first passivation layer is composed of an oxygen compound.

11. The manufacturing method of the active device as recited in claim 8, wherein the second passivation layer is composed of a nitrogen compound.

12. The manufacturing method of the active device as recited in claim 8, further comprising:
forming a planar layer on the substrate after the source and the drain are formed, wherein the planar layer covers the source, the drain and the portion of the second passivation layer exposed between the source and the drain.

13. The manufacturing method of the active device as recited in claim 8, wherein an orthogonal projection of the semiconductor section of the channel layer on the substrate is completely overlapped with an orthogonal projection of the gate on the substrate, and an area of the orthogonal projection of the semiconductor section on the substrate is less than or equal to an area of the orthogonal projection of the gate on the substrate.

14. The manufacturing method of the active device as recited in claim 8, wherein an orthogonal projection of the conductive section of the channel layer on the substrate is not overlapped with an orthogonal projection of the second passivation layer on the substrate.
